(19) United States
(12) Patent Application Publication
(10) Pub. No.: US 2009/0127096 A1
(43) Pub. Date: May 21, 2009

(54) Method for forming a corrugation multilayer

(76) Inventors: Chen-Yang Huang, Jhubel City (TW); Hao-Min Ku, Taipei City (TW); Cheng-Wei Chu, Taipei Hsien (TW); Shiuh Chao, Hsinchu (TW)

Correspondence Address: J.C Patents;Suite 250, 4 Venture, Irvine, CA, 92618, US

(21) Appl. No.: 12/008,438

(22) Filed: Jan. 10, 2008

(30) Foreign Application Priority Data
Nov. 15, 2007 (TW) 96143266

(51) Int. Cl. C23C 14/46

(52) U.S. Cl. 204/192.11

(57) ABSTRACT

A method for forming a corrugation multilayer is provided. A periodic substrate is obtained, and then a corrugated reshaping layer is formed on the periodic substrate. The corrugated reshaping layer may be formed by an ion beam sputtering system and a bias etching system. Afterward, the following steps a and b are performed repeatedly. In step a, a first capping layer is formed on the periodic substrate by the ion beam sputtering system. In step b, a second capping layer with a corrugation appearance is formed on the first capping layer by simultaneously depositing by the ion beam sputtering system and trimming by the bias etching system. The autocloning corrugation multilayer can be carried out according to this method.

### CROSS-REFERENCE TO RELATED APPLICATION

This application claims the priority benefit of Taiwan application serial no. 96143266, filed Nov. 15, 2007. The entirety of each of the above-mentioned patent application is incorporated herein by reference and made a part of this specification.

### BACKGROUND OF THE INVENTION

1. Field of the Invention

The present invention relates to a method for forming a corrugation multilayer applicable to photonic crystal.

2. Description of Related Art

Since Yabnolovitch and John came up with the concept of photonic crystals in 1987, a great many of applications and manufacturing methods have been developed. Because of periodically arranged dielectric coefficients, an electromagnetic wave has diffraction and interference phenomenon, which results in the photonic band structures of dispersion. A photonic crystal with this kind of structure is applicable to manufacturing omni-directional reflector, polarization beam splitter, super-prism, resonator, waveguide, and so on. However, it is difficult to manufacture a photonic crystal applicable in visual-light region. How to minimize the size of a photonic crystal structure into the range of sub-wavelength so as to fall band characteristics in visual-light region therefore becomes a big challenge when considering commercialization and low costs.

In 1996, Dr. T. Kawashima developed an autocloning photonic crystal, which makes use of a magnetron sputtering system to repeatedly stack the corrugated structure of a corrugation multilayer, and to simulate the photonic crystal structure by the distribution of corrugation geometric structure on the horizontal and the distribution of high and low refractive index on the vertical axis.

Thereafter, the techniques regarding the corrugated photonic crystal, which comprises periodically stacked layers of high and low refractive index, are mentioned in U.S. patents, U.S. Pat. No. 7,136,217 B1 and U.S. Pat. No. 6,977,774 B2. So far, a magnetron sputtering system is still used as a major manufacturing technique. Taking the following dissertations in 2002 as examples, “Photonic crystals for the visible range fabricated by autocloning technique and their application,” Optical and Quantum Electronics 34: 63-70, 2002, explains the use of radio frequency magnetron sputtering process in manufacturing a photonic crystal; “Tailoring of the Unit Cell Structure of Autocloned Photonic Crystals,” IEEE Journal of Quantum Electronics, Vol. 38, No. 7, pp 899, July 2002, explains the use of a continuous magnetron sputtering system and a reactive plasma etching source in manufacturing the photonic crystal.

### SUMMARY OF THE INVENTION

An embodiment of the present invention provides a method for forming a corrugation multilayer. In said method, use of an ion beam sputtering system with a bias etching system on a substrate makes the formation of a stable photonic crystal structure of the corrugation multilayer possible.

An embodiment of the present invention further provides a method for forming a corrugation multilayer. Said method coordinates the deposition rate and an etching rate of layers to stack the corrugation multilayer on a periodic substrate.

An embodiment of the present invention provides a method for forming a corrugation multilayer. Said method includes obtaining a periodic substrate first, and a corrugated reshaping layer has been formed on said periodic substrate. Then, the following processes are performed repeatedly: a) using an ion beam sputtering system to form a first capping layer on aforesaid corrugated reshaping layer; and b) depositing by the ion beam sputtering system and trimming by a bias etching system so as to form a second capping layer with a corrugation appearance on the first capping layer.

An embodiment of the present invention further provides a method for forming a corrugation multilayer, which includes obtaining an ion beam sputtering system first. Said ion beam sputtering system at least includes a vacuum chamber, a vacuum exhaust system, a target group, an ion source, a substrate base, a cooling system, a gas introduction system, and an etching system. The vacuum exhaust system is used to create a high vacuum in the vacuum chamber, and a first gas is introduced into the vacuum chamber by the gas introduction. Then, an ion beam of the ion source is bombarded a sputtering target of the target group to deposit a thin film material on the periodic substrate, and an etching plasma is formed in the periodic substrate with power supplied by the etching system to trim aforesaid thin film material so as to form a corrugated reshaping layer. Thereafter, a second gas is introduced into the vacuum chamber by the gas introduction system, and the ion beam of the ion source is again bombarded a sputtering target of the target group to form a first capping layer on the corrugated reshaping layer. The first gas is introduced into the vacuum chamber by the gas introduction system again. The ion beam of the ion source is then bombarded a sputtering target of the target group to deposit a thin film material on the first capping layer, and an etching plasma is formed in the periodic substrate with power supplied by the etching system to trim the thin film material, whereby forming a second capping layer with a corrugation appearance. The first capping layer and the second capping layer are repeatedly formed, and meanwhile, the corrugation appearance thereof is maintained.

In aforesaid ion beam sputtering system, the vacuum exhaust system is connected with the vacuum chamber to exhaust gas from the vacuum chamber. The target group is in the vacuum chamber for providing more than one kind of sputtering target. The ion source and the substrate base are both in the vacuum chamber, wherein the substrate base is used for holding aforesaid periodic substrate. The cooling system is used for cooling the target group and the vacuum chamber, and the gas introduction system is connected with the vacuum chamber to introduce a reactive gas into the vacuum chamber. The etching system is connected with the substrate base to supply an electric field so as to form etching plasma on the periodic substrate.

Making use of the ion beam sputtering system and bias etching plasma on the substrate, the present invention alternately performs deposition and etching by controlling the properties of deposition and etching plasma, or opportunely adjusts etching power when the corrugation is smoothed, so as to maintain the corrugation appearance. Consequently, a stable corrugation multilayer is formed. This method is applicable to photonic crystal technique.

In order to make aforementioned features and advantages of the present invention more comprehensible, several embodiments accompanied with figures are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A through FIG. 1C illustrate a process flow for forming a corrugation multilayer according to the first embodiment of the present invention.

FIG. 2A through FIG. 2B illustrate a process flow and equipment for forming a corrugation multilayer according to the second embodiment of the present invention.

FIG. 3 is a curve showing the relationship between the supplied power of an etching system and a corrugation multilayer in the second embodiment of the present invention.

FIG. 4A through FIG. 4C are simulated curves of capping layers, respectively corresponding to curves A, B, and C in FIG. 3.

FIG. 5 is a curve showing the relationship between a tilt angle of a substrate base and a corrugation multilayer in the second embodiment of the present invention.

FIG. 6A through FIG. 6C are stimulated curves of capping layers, respectively corresponding to curves A, B, and C in FIG. 5.

FIG. 7A is a SEM photograph of a corrugation structure in an example of the present invention.

FIG. 7B is a curve showing the relationship between the number of capping layers and the height difference of a corrugation structure in an example of the present invention.

### DESCRIPTION OF EMBODIMENTS

In the following, description with reference to figures is used to explain the embodiments of the present invention in detail. This invention, however, may be embodied in many different forms and should not be construed as limited to the embodiments set forth herein. In fact, the embodiments are provided in order to disclose the present invention more thoroughly, and to completely convey the scope of this invention to those having ordinary knowledge in this art. In the figures, in order to be clear and definite, the sizes of each layer and region, and the corresponding sizes thereof may hot be shown proportionally.

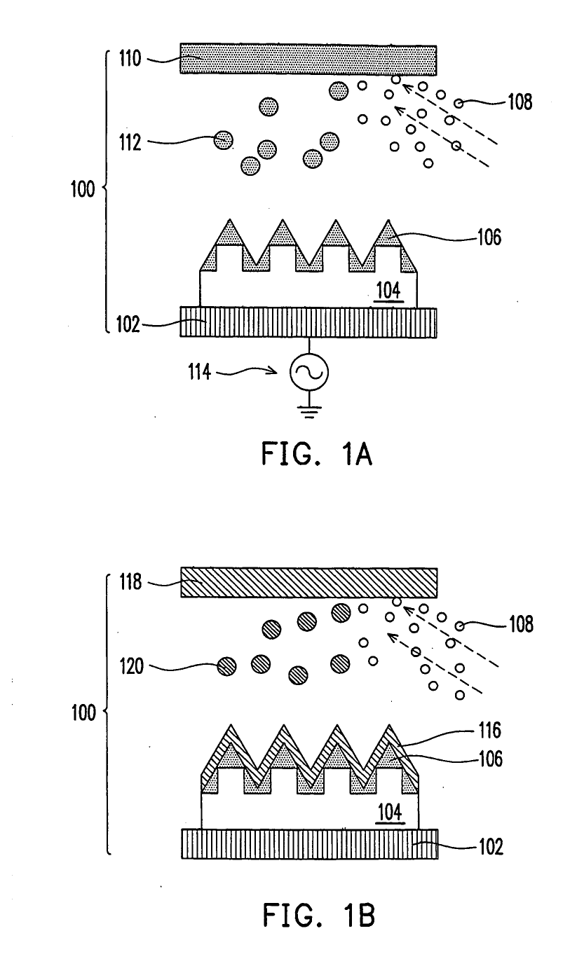

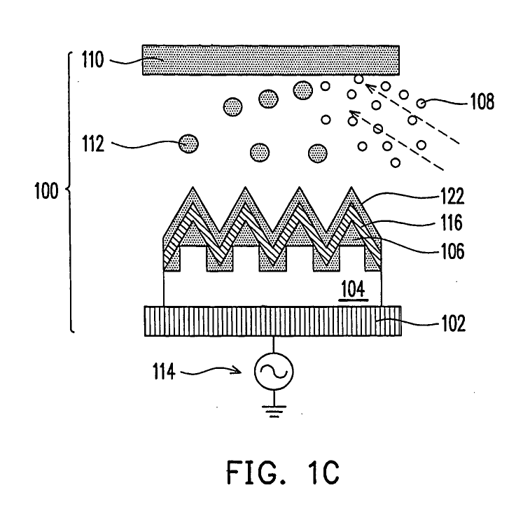

FIG. 1A through 1C illustrate a process flow for forming a corrugation Multilayer according to the first embodiment of the present invention.

Referring to FIG. 1A, a periodic substrate 104 is first provided on a substrate base 102 of an ion beam sputtering system 100, wherein a corrugated reshaping layer 106 has been formed on the periodic substrate 104. In the first embodiment, the so-called “periodic substrate” is a substrate on which a pattern is periodically arranged. As shown in FIG. 1A, a cross-sectional view of the periodic substrate 104 shows rectangular periodic protrusions. To simply the description, all elements of the ion beam sputtering system 100 are not shown in the figure of the first embodiment. In addition to existing manufacturing techniques, the method of forming said corrugated reshaping layer 106 further includes bombarding a sputtering target 110 by an ion beam 108 of the ion beam sputtering system 100 to deposit a sputtering material 112 on the periodic substrate 104, and through a bias etching system 114 connected with the substrate base 102, trimming an appearance of the deposited sputtering material 112 with a low-power etching energy so as to form the corrugated reshaping layer 106.

Then, referring to FIG. 1B, the ion beam sputtering system 100 is used to form a first capping layer 116 on the corrugated reshaping layer 106, wherein a method is, for example, bombarding a sputtering target 118 by the ion beam 108 of the ion beam sputtering system 100 to deposit a sputtering material 120. For example, a method of forming the first capping layer 116 includes depositing by an ion beam sputtering process of direct current, radio frequency, pulse, or microwave resonance.

Next, referring to FIG. 1C, a second capping layer 122 with a corrugation appearance is formed on the first capping layer 116 through depositing by the ion beam sputtering system 100 and trimming by the bias etching system 114. In particular, when the first capping layer 116 smoothes the original corrugation, aforesaid processes of deposition and trimming are performed to recover the corrugation appearance of the second capping layer 122. In FIG. 1C, the processes of deposition, for example, is performed by an ion beam sputtering process of direct current, radio frequency, pulse, or microwave resonance; and an etching, for example, is performed by a process of direct current, radio frequency, pulse, or microwave resonance.

In FIG. 1C, an ion source power of the ion beam sputtering system 100 is, for example, 100˜250 W and an ion source voltage is about 500˜1500 V. Moreover, the corrugation appearance of the second capping layer 122 is controllable by varying a power or voltage of the bias etching system 114, or by using an applied magnetic field; said corrugation appearance is also controllable by adjusting a tilt angle of the periodic substrate 104, wherein said tilt angle is about 0˜90 degrees. When the bias etching system 114 is a radio frequency bias etching system, an output bias power thereof is, for example, 1˜100 W. Besides, an inert gas and a reactive gas, for instance, are used during the formation of the second capping layer 122, wherein the inert gas is argon and the reactive gas is oxygen, nitrogen, or a combination of both, for example. Also, a design of circular introduction or porous introduction is applicable to evenly diffusing said gases on a surface of the periodic substrate 104.

Hence, the stack of the corrugation multilayer is maintainable by properly controlling sputtering plasma and etching plasma, and repeatedly performing the processes in FIG. 1B and FIG. 1C.

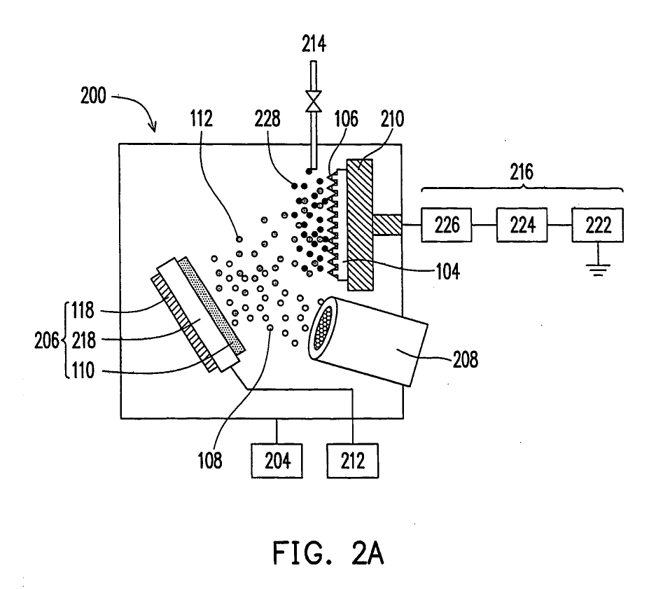

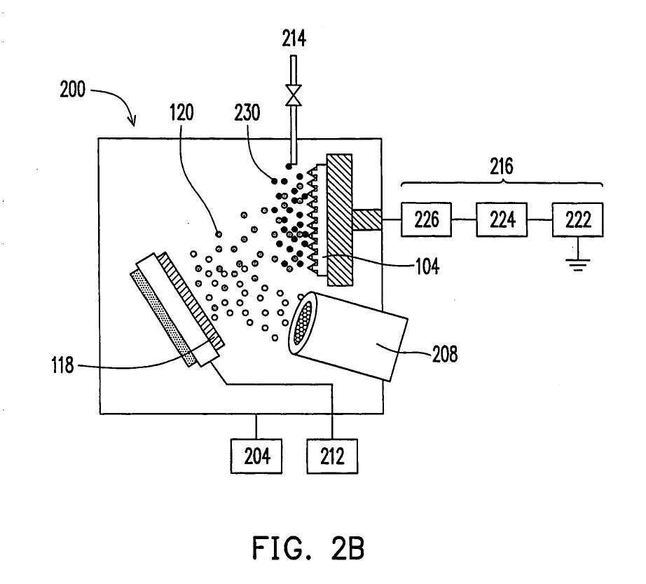

FIG. 2A through FIG. 2B illustrate a process flow and equipment for forming a corrugation multilayer according to the second embodiment of the present invention, wherein reference numbers in the first embodiment are used in the second embodiment to represent the same elements.

Referring to FIG. 2A, a method of the second embodiment is to provide an ion beam sputtering system 200 first. The ion beam sputtering system 200 at least includes a vacuum chamber 202 (not shown), a vacuum exhaust system 204, a target group 206, an ion source 208, a substrate base 210, a cooling system 212, a gas introduction system 214, and an etching system 216. In aforesaid ion beam sputtering system 200, the vacuum exhaust system 204 is connected with the vacuum chamber 202 to exhaust gas from the vacuum chamber 202. The target group 206 is in the vacuum chamber 202 and provides more than one kind of sputtering target; as shown in FIG. 2, the target group 206 includes a substrate 218 and two kinds of sputtering targets 110 and 118. The ion source 208 and the substrate base 210 are both in the vacuum chamber 202, wherein the ion source 208 is used for performing ion beam sputtering and the substrate base 210 is used for holding the periodic substrate 104. The cooling system 212 is used for cooling the target group 206 and the vacuum chamber 202, and the gas introduction system 214 is connected with the vacuum chamber 202 to introduce a reactive gas into the vacuum chamber 202. The ion beam sputtering system 200 is a system depositing by direct current, radio frequency, pulse, or microwave resonance. The etching system 216 is connected with the substrate base 210 to provide an electric field so as to form etching plasma on the periodic substrate 104, wherein the etching system 216 is, for example, a power supply system of direct current, radio frequency, pulse, or microwave resonance. In this figure, the etching system 216 is a kind of radio frequency power supply system is, for example, a RF power supply 222, a RF generator 224, and a matching box 226.

Referring to FIG. 2A, the vacuum exhaust system 204 is used to create a high vacuum (below 10⁻⁶ Pa, for example) in the vacuum chamber 202, and a first gas 228 is introduced into the vacuum chamber 202 by the gas introduction system 214, wherein the first gas 228 includes a inert gas and/or a reactive gas. Thereafter, the sputtering target 110 of the target group 206 is bombarded by the ion beam 108 of the ion source 208 to deposit a thin film material on the periodic substrate 104, and an etching plasma is formed on the periodic substrate 104 with power supplied by the etching system 216 so as to perform a process for trimming the thin film material till the corrugated reshaping layer 106 is formed. Wherein, a power of the ion source 208 is 100˜250 W and a voltage of the ion source 208 is 500˜1500 V, for example. A bias power of the etching system 216 is, for example, an output power of 1˜100 W.

Then, referring to FIG. 2B, a second gas 230 is introduced into the vacuum chamber 202 by the gas introduction system 214, wherein the second gas 230 includes an inert gas and/or a reactive gas. The sputtering target 118 is bombarded by the ion beam 108 of the ion source 208 to form a capping layer (not shown) on the corrugated reshaping layer 106. Thereafter, the processes in FIG. 2A and FIG. 2B are performed repeatedly. The capping layers are formed by ion beam sputtering and the radio frequency plasma trims a corrugation appearance. Through trimming several layers with stacking by the ion beam sputtering, the corrugation appearance will be maintained in the corrugation multilayer.

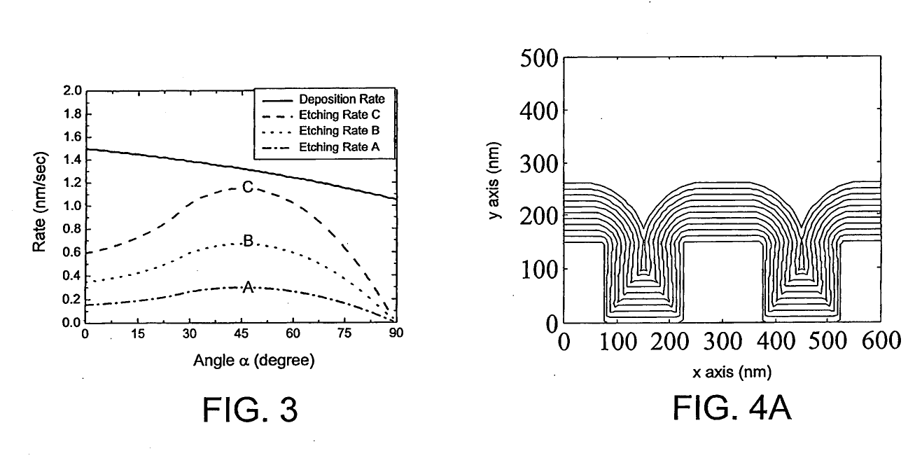

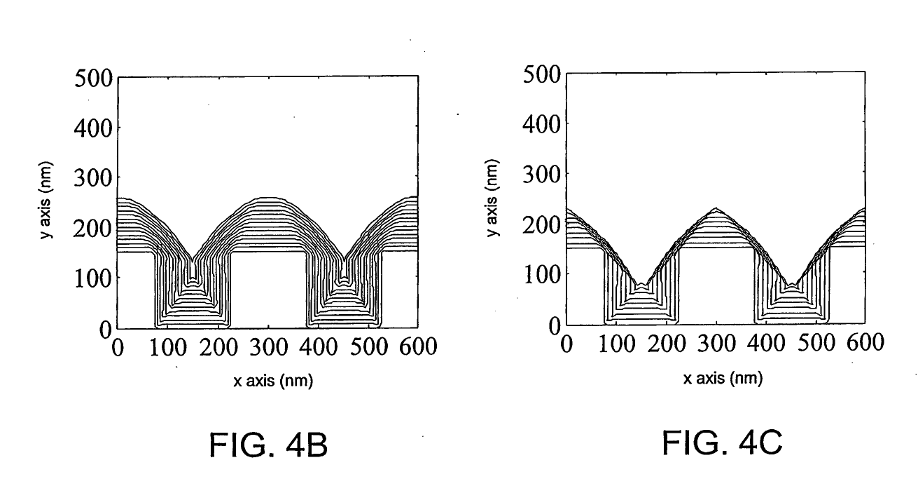

In the second embodiment, the corrugation appearance of the capping layers is controllable by further varying the power or voltage of the etching system 216, or using an applied magnetic field; for example, the appearance of the multilayer is controllable by changing the power of the etching system 216. As shown in FIG. 3, wherein the vertical axis represents rate and the horizontal axis represents an angle α between a normal line of the surface of the capping layers and an injection direction of etching plasma. Curve A represents RF Bias power is 0˜10 W, Curve B represents RF Bias power is 10˜30 W, and Curve C represents RF Bias power is 30˜50 W. FIG. 4A through FIG. 4C are simulated curves of capping layers, respectively corresponding to curves A, B, and C in FIG. 3.

As shown in FIG. 4A through FIG. 4C, the adjustment in the power of the etching system 216 changes the appearance of capping layers from a distribution of arcs into a distribution of triangles.

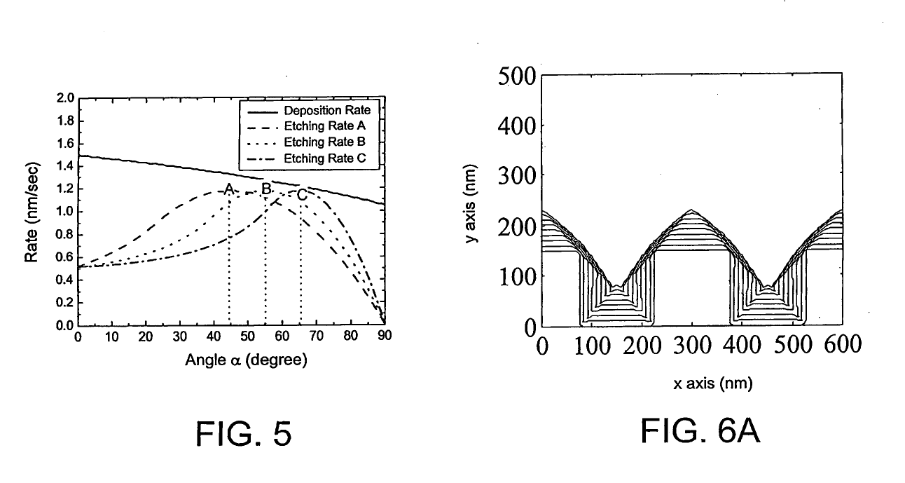

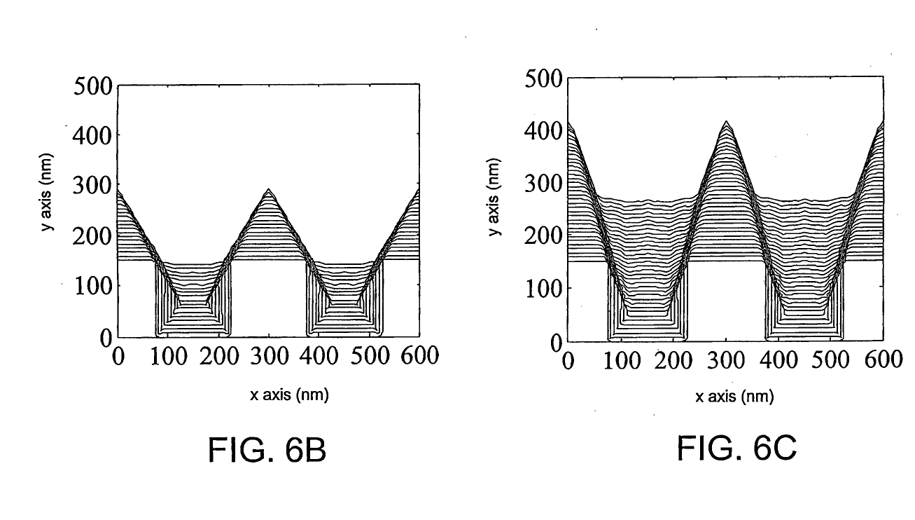

Moreover, in the second embodiment, the corrugation appearance (stacking angle of the corrugation) of capping layers is controllable by adjusting a tilt angle of the substrate base 210 to move etching curves leftward or rightward, wherein the tilt angle is about 0˜90 degrees. As shown in FIG. 5, wherein the vertical axis represents rate and the horizontal axis represents an angle α between a normal line of the surface of capping layers and an injection direction of etching plasma. In FIG. 5, Curve A represents that the substrate base 210 is horizontal, Curve B represents that a tilt angle of the substrate base is 5˜10 degrees, and Curve C represents that a tilt angle of the substrate base is 10˜15 degrees. FIG. 6A through FIG. 6C are simulated curves of capping layers, respectively corresponding to curve A, B, and C in FIG. 5. As shown in FIG. 6A through FIG. 6C, the adjustment in a tilt angle of the substrate base 210 changes the appearance of capping layers from a distribution of steep triangles into a distribution of steep triangles.

The following is an example according to a method of the second embodiment.

### Example

When the second embodiment is applied to manufacturing photonic crystals, specific process parameters in Table I through Table 3 are applicable to forming a 61-layer corrugation multilayer, wherein Table I shows the parameters of a corrugated reshaping layer (ex. Ta₂O₅), Table 2 shows the parameters of a first capping layer (ex. SiO₂), and Table 3 shows the parameters of a second capping layer (ex. Ta₂O₅).

TABLE 1
Material of the corrugated reshaping layer: Ta₂O₅
Target: Ta

| | |
|---|---|
| Unit | Parameter |

Deposition process

| | | |
|---|---|---|
| Power of ion source | W | 190 |
| Voltage of ion source | V | 1000 |
| Current of ion source | mA | 145 |
| Introduced gas (argon) | sccm | 10 |

Etching process

| | | |
|---|---|---|
| RF power | W | 45 |
| Introduced gas (oxygen) | sccm | 10 |

TABLE 2
Material of the first capping layer: SiO₂
Target: SiO₂

| | |
|---|---|
| Unit | Parameter |

Deposition process

| | | |
|---|---|---|
| Power of ion source | W | 190 |
| Voltage of ion source | V | 1000 |
| Current of ion source | mA | 145 |
| Introduced gas (argon) | sccm | 10 |

TABLE 3
Material of the second capping layer: Ta₂O₅
Target: Ta

| | |
|---|---|
| Unit | Parameter |

Deposition process

| | | |
|---|---|---|
| Power of ion source | W | 190 |
| Voltage of ion source | V | 1000 |
| Current of ion source | mA | 145 |
| Introduced gas (argon) | sccm | 10 |

Etching process

| | | |
|---|---|---|
| RF power | W | 30 |
| Introduced gas (oxygen) | sccm | 10 |

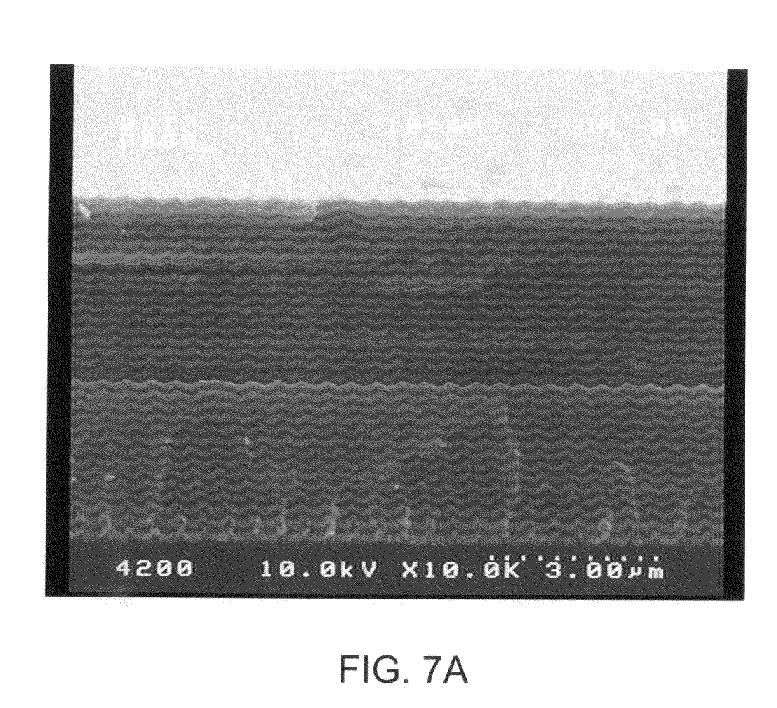

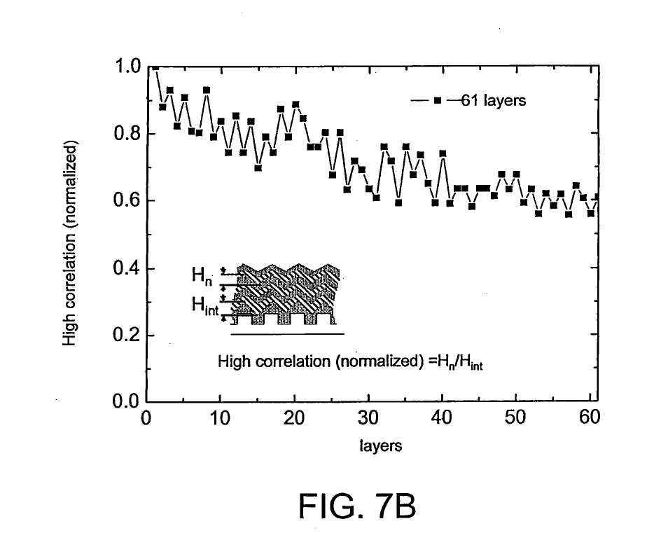

FIG. 7A is a SEM photograph of the 61-layer corrugation multilayer. As shown in FIG. 7A, each of the capping layers has an obvious corrugation appearance.

The correlation between the height difference of corrugation structure of each layer and the maintenance of corrugation is shown in FIG. 7B.

In FIG. 7B, high correlation (normalized) represents the proportion between the height Hᵢₙₜ of the triangle structures in a cross-sectional view of the corrugated reshaping layer and the height Hₙ of the triangle structures in a cross-sectional view of a Nth capping layer above. As shown in FIG. 7B, after stacking 61 capping layers, the maintenance of the triangle structure is relatively stable, and the maintenance of the shape is about 60% (high correlation (normalized) is about 0.6).

To sum up, the present invention makes use of an ion beam sputtering system and a bias etching system corresponding to a substrate, and alternately controls the deposition rate and etching rate of capping layers to form a stacked appearance of reshaping capping layers, so as to form a corrugation multilayer.

Although the present invention has been disclosed above by the embodiments, they are not intended to limit the present invention. Anybody skilled in the art can make some modifications and alteration without departing from the spirit and scope of the present invention. Therefore, the protecting range of the present invention falls in the appended claims.

What is claimed is:

1. A method for forming a corrugation multilayer, comprising:
obtaining a periodic substrate on which a corrugated reshaping layer is formed;
a) forming a first capping layer on the corrugated reshaping layer by an ion beam sputtering system;
b) forming a second capping layer with a corrugation appearance on the first capping layer through depositing by the ion beam sputtering system and trimming by a bias etching system; and
performing step a and step b repeatedly.

2. The method of claim 1, wherein a method for forming the first capping layer in step a comprises depositing by an ion beam sputtering process of direct current, radio frequency, pulse, or microwave resonance.

3. The method of claim 1, wherein a method for depositing by the ion beam sputtering system in step b comprises depositing by the ion beam sputtering process of direct current, radio frequency, pulse, or microwave resonance.

4. The method of claim 1, wherein an ion source power of the ion beam sputtering system is 100˜250 W and an ion source voltage of the ion beam sputtering system is 500˜1500 V.

5. The method of claim 1, wherein step b comprises varying a power or a voltage of the bias etching system or using an applied magnetic field to control the corrugation appearance of the second capping layer.

6. The method of claim 1, wherein step b comprises adjusting a tilt angle of the periodic substrate to control the corrugation appearance of the second capping layer, and the tilt angle is 0˜90 degrees.

7. The method of claim 1, wherein a method for trimming by the bias etching system in step b comprises etching by direct current, radio frequency, pulse, or microwave resonance.

8. The method of claim 7, wherein a bias power of radio frequency etching in step b is an output power of 1˜100 W.

9. The method of claim 1, wherein step a and step b comprise using an inert gas or a reactive gas.

10. The method of claim 9, wherein the inert gas comprises argon and the reactive gas comprises oxygen, nitrogen or a combination thereof.

11. The method of claim 1, wherein step a and step b comprise using a design of circular introduction or porous introduction to evenly diffuse a gas on a surface of the periodic substrate.

12. The method of claim 1, wherein a method for forming the corrugated reshaping layer comprises depositing by the ion beam sputtering system and trimming by the bias etching system so as to form the corrugated reshaping layer on the periodic substrate.

13. A method for forming a corrugation multilayer, comprising:
obtaining an ion beam sputtering system which at least comprises:
a vacuum chamber;
a vacuum exhaust system, connected with the vacuum chamber for exhausting a gas from the vacuum chamber;
a target group in the vacuum chamber for providing more than one kind of sputtering targets;
an ion source in the vacuum chamber;
a substrate base in the vacuum chamber, for holding a periodic substrate thereon;
a cooling system for cooling the target group and the vacuum chamber;
a gas introduction system, connected with the vacuum chamber for introducing the gas to the vacuum chamber; and
an etching system, connected with the substrate base for supplying an electric field to form etching plasma on the periodic substrate;
using the vacuum exhaust system to create a high vacuum in the vacuum chamber;
introducing a first gas through the gas introduction system into the vacuum chamber;
bombarding a sputtering target of the target group by an ion beam of the ion source to deposit a thin film material on the periodic substrate, and forming an etching plasma, powered by the etching system, in the periodic substrate to trim the thin film material so as to form a corrugated reshaping layer;
introducing a second gas through the gas introduction system into the vacuum chamber;
bombarding the sputtering target of the target group by the ion beam of the ion source so as to form a first capping layer on the corrugated reshaping layer;
introducing the first gas through the gas introduction system into the vacuum chamber;
bombarding the sputtering target of the target group by the ion beam of the ion source to deposit the thin film material on the first capping layer, and forming an etching plasma, powered by the etching system, in the periodic substrate to trim the thin film material so as to form a second capping layer with a corrugation appearance; and
repeatedly forming the first capping layer and the second capping layer in order to maintain the corrugation appearance thereof.

14. The method of claim 13, wherein the ion beam sputtering system comprises depositing by direct current, radio frequency, pulse, or microwave resonance.

15. The method of claim 13, wherein a power of the ion source is 100˜250 W and a voltage of the ion source is 500˜1500 V.

16. The method of claim 13, wherein a method for trimming the thin film material comprises: varying a power or a voltage of the etching system, or using an applied magnetic field to control the corrugation appearance of the second capping layer.

17. The method of claim 13, wherein the method for trimming the thin film material comprises adjusting a tilt angle of the substrate base to control the corrugation appearance of the second capping layer, and the tilt angle is 0˜90 degrees.

18. The method of claim 13, wherein a bias power of the etching system for trimming the thin film material is an output power of 1˜100 W.

19. The method of claim 13, wherein the etching system comprises a power supply system of direct current, radio frequency, pulse, or microwave resonance.

20. The method of claim 13, wherein the first gas and the second gas comprise an inert gas or a reactive gas.

21. The method of claim 20, wherein the inert gas comprises argon and the reactive gas comprises oxygen, nitrogen, or a combination of both.

22. The method of claim 13, wherein a method for introducing the first gas and the second gas comprises using a design of circular introduction or porous introduction to evenly diffuse the gas on the surface of the periodic substrate.
